(19) United States
(12) Patent Application Publication
(10) Pub. No.: US 2024/0324173 A1
(43) Pub. Date: Sep. 26, 2024

(54) MEMORY DEVICE WITH SEMICONDUCTOR ELEMENTS

(71) Applicant: Unisantis Electronics Singapore Pte. Ltd., Singapore (SG)

(72) Inventors: Masakazu KAKUMU, Tokyo (JP); Koji Sakui, Tokyo (JP); Nozomu Harada, Tokyo (JP)

(21) Appl. No.: 18/609,227

(22) Filed: Mar. 19, 2024

(30) Foreign Application Priority Data
Mar. 23, 2023 (WO) PCT/JP2023/011541

(51) Int. Cl. H10B 12/00

(52) U.S. Cl. CPC H10B 12/20

(57) ABSTRACT

A dynamic flash memory is provided that includes a first gate conductor layer and a second gate conductor layer isolated from each other, a first gate insulating layer covering the first gate conductor layer, a second gate insulating layer covering the second gate conductor layer, a p layer provided in contact with each gate insulating layer such that the p layer covers the periphery of each gate insulating layer, an n⁺ layer provided in contact with one side of the p layer in the axial direction, and another n⁺ layer provided in contact with the other side thereof.

### CROSS REFERENCE TO RELATED APPLICATIONS

This application claims priority to PCT/JP2023/011541, filed Mar. 23, 2023, the entire content of which is incorporated herein by reference.

### BACKGROUND OF THE INVENTION

### Field of the Invention

The present invention relates to a memory device with semiconductor elements.

### Description of the Related Art

In recent years, there has been a demand for a higher degree of integration, higher performance, lower power consumption, and higher functionality of memory devices with semiconductor elements in the development of the LSI (Large Scale Integration) technology.

Memory devices with semiconductor elements have been developed with the aim of increasing density and performance. Using SGTs (Surrounding Gate Transistors; see Japanese Patent Laid-Open No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) as selection transistors can provide, for example, a DRAM (Dynamic Random Access Memory) with a capacitor connected thereto (for example, see H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)), a PCM (Phase Change Memory) with a variable resistance element connected thereto (for example, see H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)), an RRAM (Resistive Random Access Memory; for example, see K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007), and an MRAM (Magneto-resistive Random Access Memory) whose resistance is changed by changing the direction of a magnetic spin using a current (for example, see W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)).

There is also known a capacitorless DRAM memory cell including a single MOS transistor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010), J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012), Takashi Ohsawa and Takeshi Hamamoto, “Floating Body Cell—a Novel Body Capacitorless DRAM Cell”, Pan Stanford Publishing (2011), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006), and E. Yoshida and T. Tanaka: “A Capacitorless 1T-DRAM Technology Using Gate-Induced Drain-Leakage (GIDL) Current for Low-Power and High-Speed Embedded Memory,” IEEE IEDM (2006)), for example. In such a memory cell, logical memory data “1” is written by retaining some of holes in a floating body. Meanwhile, logical memory data “0” is written by removing the holes from the floating body. For the memory cell, it is desired to improve a decrease in the operation margin due to fluctuation of a voltage in the channel with a floating body structure, and also improve degradation of the data retention characteristics resulting from the removal of some of the holes that are the charge carriers stored in the channel.

There is also known a twin-transistor-based MOS transistor memory element obtained by forming a single memory cell in an SOI layer using two MOS transistors (for example, see US2008/0137394 A1, US2003/0111681 A1, and F. Morishita, H. Noda, I. Hayashi, T. Gyohten, M. Okamoto, T. Ipposhi, S. Maegawa, K. Dosaka, and K. Arimoto: “Capacitorless Twin-Transistor Random Access Memory (TTRAM) on SOI,” IEICE Trans. Electron., Vol. E90-c, No. 4 pp. 765-771 (2007)). Further, there is also known a capacitorless dynamic flash memory (DFM) obtained by forming a single memory cell using two gate electrodes (see K. Sakui, N. Harada, “Dynamic Flash Memory with Dual Gate Surrounding Gate Transistor (SGT),” Proc. IEEE IMW, pp. 72-75(2021)). In such a memory cell, a memory operation is performed by controlling the voltages of four electrodes to change the concentration of carriers in a floating body, and thus creating a conductive state or a non-conductive state. However, regarding a three-dimensional floating-body memory in which a semiconductor is covered with gate insulating layers and gate electrodes, if the memory size is reduced, the volume of the memory for storing excess holes would decrease, resulting in a smaller memory margin, which is problematic. Further, since a line of electric force from the gate electrodes concentrates in the semiconductor from the neighboring regions, the back-gate bias effect would decrease. This makes it difficult to distinguish between the written state and the erase state. That is, the margin between “1” and “0” becomes small, which is problematic.

An object of the present invention is to provide methods for stably writing, erasing, and reading memory information to/from a dynamic flash memory that is a memory device.

### SUMMARY OF THE INVENTION

To solve the foregoing problems, a memory device with semiconductor elements according to a first invention includes a first gate conductor layer and a second gate conductor layer extending in a horizontal direction or a vertical direction on a substrate, the first gate conductor layer and the second gate conductor layer being electrically isolated from each other by an insulating layer; a first gate insulating layer partially covering the first gate conductor layer; a second gate insulating layer partially covering the second gate conductor layer; a semiconductor region in contact with each of the first gate insulating layer and the second gate insulating layer, the semiconductor region extending in parallel with an extension direction of the first and second gate conductor layers; and a first impurity region and a second impurity region that are respectively continuous with opposite ends of the semiconductor region in the extension direction, and are electrically isolated from each other, in which, as seen in a horizontal cross-section, a length of the semiconductor region in contact with the first gate insulating layer is longer than a length of the first gate conductor layer in contact with the first gate insulating layer, or a length of the semiconductor region in contact with the second gate insulating layer is longer than a length of the second gate conductor layer in contact with the second gate insulating layer.

In a second invention according to the foregoing first invention, as seen in a cross-section perpendicular to the extension direction of the first gate conductor layer and the second gate conductor layer, an outer peripheral length of the semiconductor region is greater than an outer peripheral length of the first gate conductor layer or the second gate conductor layer.

In a third invention according to the foregoing first invention, the first impurity region is in contact with the semiconductor region at two or more positions.

In a fourth invention according to the foregoing first invention, the second impurity region is in contact with the semiconductor region at two or more positions.

In a fifth invention according to the foregoing first invention, the first impurity region is connected to a source line, the second impurity region is connected to a bit line, one of the first gate conductor layer and the second gate conductor layer is connected to a word line, and the other of the first gate conductor layer and the second gate conductor layer is connected to a plate line, and an operation of a dynamic flash memory is performed by applying a voltage to each of the source line, the bit line, the plate line, and the word line to execute a memory write operation, a memory read operation, and a memory erase operation.

### BRIEF DESCRIPTION OF THE DRAWINGS

FIGS. 1AA, 1AB and 1AC are views illustrating a cross-sectional structure, a planar structure, and an overhead view, respectively, of a memory device with semiconductor elements according to the present embodiment.

FIGS. 1BA, 1BB, 1BC and 1BD are views each illustrating an example of the application of the memory device with semiconductor elements according to the present embodiment.

FIGS. 2A, 2B and 2C are views for describing the storage of hole carriers and a cell current during a write operation for the memory device with semiconductor elements according to the present embodiment.

FIGS. 3A and 3B are views for describing an erase operation for the memory device with semiconductor elements according to the present embodiment.

### DETAILED DESCRIPTION OF THE PREFERRED EMBODIMENTS

Hereinafter, the structure of a memory device with semiconductor elements, a driving scheme therefor, and the behavior of carriers stored therein according to an embodiment of the present invention will be described with reference to the drawings.

### Present Embodiment

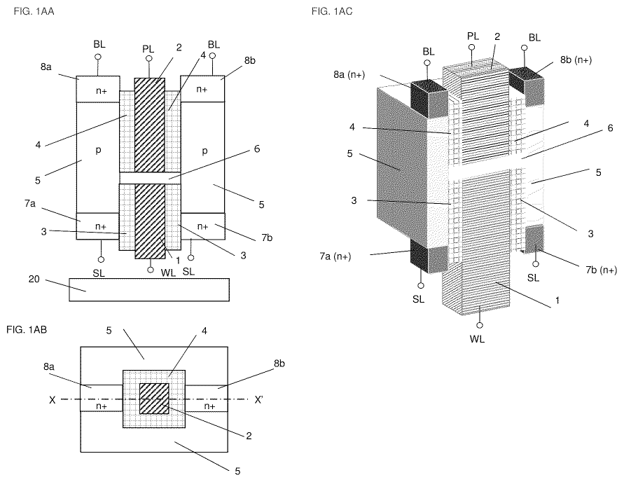

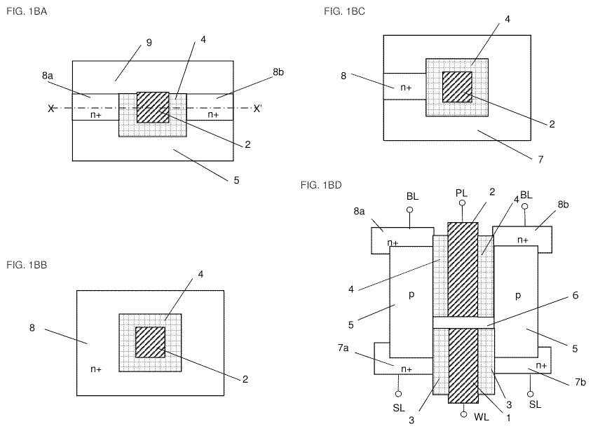

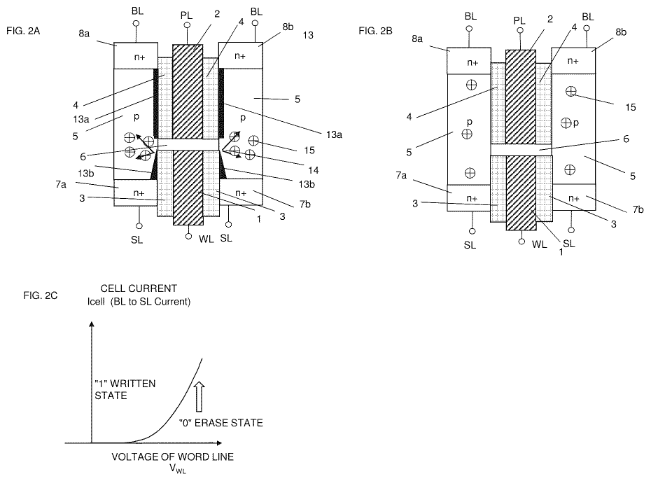

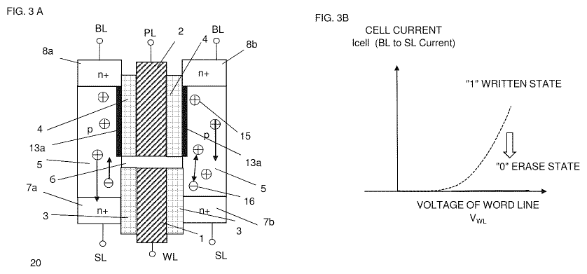

The structure and the operation mechanism of a memory cell with semiconductor elements according to an embodiment of the present invention will be described with reference to FIGS. 1AA to 3B. First, the structure of the memory cell with semiconductor elements according to the present embodiment will be described with reference to FIGS. 1AA to 1BD. Next, the mechanism of writing data to the memory cell with semiconductor elements, and the behavior of carriers therein will be described with reference to FIGS. 2A to 2C. Then, the mechanism of the operation of erasing data will be described with reference to FIGS. 3A and 3B.

FIGS. 1AA to 1AC illustrate the structure of the memory cell with semiconductor elements according to the present embodiment of the present invention. Specifically, FIG. 1AA is a vertical cross-sectional view, FIG. 1AB is a top plan view, and FIG. 1AC is an overhead view illustrating a cross-section of the cell along line X-X′ in FIG. 1AB. FIGS. 1BA to 1BD illustrate examples of the application of the present embodiment.

A first gate conductor layer 1 (which is an example of a “first gate conductor layer” in the claims) and a second gate conductor layer 2 (which is an example of a “second gate conductor layer” in the claims) are provided in the vertical direction on a substrate 20 (which is an example of a “substrate” in the claims) such that they are electrically isolated from each other by an insulating layer 6. A first gate insulating layer 3 (which is an example of a “first gate insulating layer” in the claims) is provided such that it partially covers the first gate conductor layer. A second gate insulating layer 4 (which is an example of a “second gate insulating layer” in the claims) is provided such that it partially covers the second gate conductor layer 2. A p layer 5, which is a silicon semiconductor with p-type or i-type (intrinsic) conductivity containing acceptor impurities (which is an example of a “semiconductor region” in the claims), is provided in contact with each of the first gate insulating layer 3 and the second gate insulating layer 4. On one side of the p layer 5 in the vertical direction, n⁺ layers 7a and 7b (hereinafter, a semiconductor region containing a high concentration of donor impurities shall be referred to as an “n⁺ layer”) (which are examples of a “first impurity region” in the claims) is provided. Hereinafter, the n⁺ layers 7a and 7b may be collectively referred to as an n⁺ layer 7. On the opposite side of the n′ layers 7a and 7b, n⁺ layers 8a and 8b (which are examples of a “second impurity region” in the claims) are provided. Hereinafter, the n⁺ layers 8a and 8b may be collectively referred to as an n⁺ layer 8. The n⁺ layer 7 and the n⁺ layer 8 are electrically isolated from each of the first gate conductor layer 1 and the second gate conductor layer 2.

Consequently, the p layer 5, the first gate conductor layer 1, the first gate insulating layer 3, the second gate conductor layer 2, the second gate insulating layer 4, the n⁺ layer 7a, the n⁺ layer 7b, the n⁺ layer 8a, and the n⁺ layer 8b form a single dynamic flash memory cell.

Further, the n⁺ layer 7 is connected to a source line SL (which is an example of a “source line” in the claims) as a wire conductor, the first gate conductor layer 1 is connected to a word line WL (which is an example of a “word line” in the claims) as a wire conductor, and the second gate conductor layer 2 is connected to a plate line PL (which is an example of a “plate line” in the claims) as a wire conductor. In addition, the n⁺ layer 8 is connected to a bit line BL (which is an example of a “bit line” in the claims) as a wire conductor. The dynamic flash memory operation is performed by controlling the potential of each of the source line, the bit line, the plate line, and the word line.

In the memory device of the present embodiment, the foregoing plurality of dynamic flash memory cells are partially isolated from each other by insulators, and are arranged two-dimensionally or three-dimensionally. Although the present embodiment illustrates an example in which the p layer 5 is formed vertically to the substrate 20, the present embodiment is also applicable to a case where the p layer 5 is formed horizontally to the substrate 20.

Note that FIG. 1AA illustrates an example of a structure in which, as illustrated in FIG. 1AB, the periphery of the second gate conductor layer 2 is entirely covered with the second gate insulating layer 4 and the p layer 5. However, as illustrated in FIG. 1BA, for example, as long as the second gate conductor layer 2 is electrically isolated from the p layer 5, the dynamic flash memory may also be formed such that the second gate insulating layer 4 and the p layer 5 partially cover the periphery of the second gate conductor layer, and an insulating layer 9 covers the other portion of the second gate conductor layer. This is also true of the relationship among the first gate conductor layer 1, the first gate insulating layer 3, and the p layer 5.

Although FIG. 1AA to 1AC illustrate an example in which the n⁺ layer 7a/7b or the n⁺ layer 8a/8b is provided at two positions on the lower surface or the upper surface of the p layer 5, the dynamic flash memory operation can also be performed with a structure in which, as illustrated in FIG. 1BB, an n⁺ layer is formed in contact with the p layer 5 such that it is formed on the entire surface of the p layer 5, or a structure in which, as illustrated in FIG. 1BC, the n⁺ layer 8 is formed only at one position. Further, as illustrated in FIG. 1BD, the n⁺ layers 7 and 8 may be formed in contact with the side surfaces of the p layer 5.

For the second gate insulating layer 4, any insulating film used in the common MOS process can be used, such as a SiO₂ film, a SiON film, a HfSiON film, or a stacked film of SiO₂/SiN, for example.

Although the p layer 5 is a p-type semiconductor in FIGS. 1AA to FIG. 1BD, the concentration of the impurities therein may have a profile. In addition, the concentration of the impurities in each of the n⁺ layer 7 and the n⁺ layer 8 may also have a profile. An LDD (Lightly Doped Drain) may also be provided between the p layer 5 and each of the n⁺ layer 7 and the n⁺ layer 8.

When each of the n⁺ layer 7 and the n⁺ layer 8 is formed using a p⁺ layer containing holes as the majority carriers (hereinafter, a semiconductor region containing a high concentration of acceptor impurities shall be referred to as a “p⁺ layer”), forming the p layer 5 using an n-type semiconductor can perform the dynamic flash memory operation by using electrons as the carriers for writing.

Each of the first gate conductor layer 1 and the second gate conductor layer 2 may be formed using metal or metal nitride, such as W, Pd, Ru, Al, TiN, TaN, or WN; an alloy (including silicide) thereof, such as a stacked structure of TiN/W/TaN; or a heavily doped semiconductor as long as the first gate conductor layer 1 can change the potential of part of the memory cell via the first gate insulating layer 3 and the second gate conductor layer 2 can change the potential of part of the memory cell via the second gate insulating layer 4.

Although FIG. 1AA illustrates an example in which the memory cell has a rectangular vertical cross-section as seen in the direction parallel to the sheet surface, the vertical cross-section may be trapezoidal, polygonal, elliptical, or circular.

The behavior of carriers, the storage of the carriers, and a cell current during a write operation for the dynamic flash memory according to the present embodiment of the present invention will be described with reference to FIGS. 2A to 2C. As illustrated in FIG. 2A, first, a case will be described where the majority carriers in the n⁺ layer 7a/7b and the n⁺ layer 8a/8b are electrons, n⁺ poly (hereinafter, poly Si containing a high concentration of donor impurities shall be referred to as “n⁺ poly”) is used for the first gate conductor layer 1 connecting to the word line WL and for the second gate conductor layer 2 connecting to the plate line PL, for example, and a p-type semiconductor is used for the p layer 5. To write data to the dynamic flash memory, it is necessary to cause sufficient impact ionization. 0 V is input to the source line SL connected to the n⁺ layer 7, for example, 1.0 V is input to the bit line BL connected to the n⁺ layer 8, for example, 2.0 V is input to the plate line PL connected to the second gate conductor layer 2, for example, and 1.2 V is input to the first gate conductor layer 1 connected to the word line WL, for example.

In such a voltage applied state, an inversion layer 13a is formed in the p layer 5 on the outer side of the second gate insulating layer 4, specifically, on the entire surface of an interface with the second gate insulating layer 4. In addition, an inversion layer 13b is formed in the p layer 5 on the outer side of the first gate insulating layer 3, specifically, on part of an interface with the first gate insulating layer 3. A pinch-off point 14 at which the inversion layer 13b disappears is present at the interface between the first gate insulating layer 3 and the p layer 5, and an electric field becomes maximum at the pinch-off point 14. Then, electrons flow in the direction from the n⁺ layer 7 to the n⁺ layer 8. Consequently, an impact ionization phenomenon occurs in a region around the pinch-off point 14. Due to the impact ionization phenomenon, electrons accelerated toward the n⁺ layer 8 connected to the bit line BL from the n⁺ layer 7 connected to the source line SL collide with Si lattices, and electron-hole pairs are generated due to the kinetic energy. Some of the generated electrons flow into the first gate conductor layer 1 and the second gate conductor layer 2, but most of them flow into the n⁺ layer 8 connected to the bit line BL. Meanwhile, excess holes 15 are gradually stored in the p layer 5.

FIG. 2B illustrates the holes 15 in the p layer 5 when all biases have become 0 V immediately after the writing. The generated holes 15 are the majority carriers in the p layer 5, and are temporarily stored in the p layer 5, and thus charge the p layer 5 in a positively biased manner. Consequently, the flat-band value of the MOS structure formed with the first gate conductor layer 1 and the second gate conductor layer 2 becomes lower. Thus, as illustrated in FIG. 2C, it becomes easier for a cell current to flow from the n⁺ layer 8 to the n⁺ layer 7 at a lower voltage of the word line. Such a written state is allocated as logical memory data “1.”

In addition to the foregoing example, the voltages applied to the bit line BL (represented by VBL), the source line SL (represented by VSL), the word line WL (represented by VWL), and the plate line PL (represented by VPL) may be other combinations, such as 1.0 V (VBL)/0 V (VSL)/2.0 V (VPL)/2.0 V (VWL), 1.5V (VBL)/0 V (VSL)/3.0 V (VPL)/1.0 V (VWL), and 1.0 V (VBL)/0 V (VSL)/1.2 V (VPL)/2.0 V (VWL). The voltage relationship between the bit line BL and the source line SL may also be reversed.

An example of the erase operation for the dynamic flash memory of the present embodiment illustrated in FIGS. 1AA to 1BD will be described with reference to FIGS. 3A and 3B. In the state illustrated in FIG. 2B, a voltage of 0.6 V is applied to the bit line BL, a voltage of 0 V is applied to the source line SL, a voltage of 2 V is applied to the plate line PL, and a voltage of 0 V is applied to the word line WL. Consequently, as the concentration of the holes 15 stored in the p layer 5 is sufficiently higher than the concentration of holes in the n′ layer 7, the holes flow into the n⁺ layer 7 due to diffusion because of the concentration gradient. Conversely, as the concentration of electrons in the n⁺ layer 7 is higher than the concentration of electrons in the p layer 5, electrons 16 flow into the p layer 5 due to diffusion because of the concentration gradient. The electrons that have flowed into the p layer 5 recombine with the holes in the p layer 5, and thus disappear. However, not all of the injected electrons 16 disappear, and the electrons 16 that have not disappeared flow into the n⁺ layer 8 by drifting due to the potential gradient between the bit line BL and the source line SL. Since the electrons are supplied from the source line SL one after another, the excess holes recombine with the electrons in quite a short time, and thus return to the initial state. In addition, the inversion layer 13a formed between the second the gate insulating layer 4 and the p layer 5 increases chances for recombination of holes and electrons, and thus accelerates the erase operation. That is, the flat-band value of the MOS structure formed with the first gate conductor layer 1 and the second gate conductor layer 2 becomes higher. Such an erase state of the memory element corresponds to logical memory data “0” because no cell current flows as illustrated in FIG. 3B.

As a method of erasing data other than that exemplarily described above, the conditions of the voltages applied to the bit line BL, the source line SL, the word line WL, and the plate line PL may be other combinations, such as 0.6 V (VBL)/0 V (VSL)/2.0 V (VPL)/0 V (VWL), 0.6 V (VBL)/0 V (VSL)/2.0 V (VPL)/0.2 V (VWL), and 1.5 V (VBL)/0 V (VSL)/2.0 V (VPL)/0 V (VWL). The foregoing conditions of the voltages applied to the bit line BL, the source line SL, the word line WL, and the plate line PL are only examples for performing a memory erase operation. Thus, any other operating voltage conditions that allow for a memory erase operation may be used.

Although FIGS. 1AA to 3B illustrate examples in which the n⁺ layers 7 and 8 are provided and the majority carriers for writing are holes, the present invention is similarly applicable to each of a write operation, an erase operation, and a read operation when p⁺ layers are provided instead of the n⁺ layers and the majority carriers for writing are electrons.

As described in the present embodiment, the present dynamic flash memory cell may have any structure that satisfies the condition that the holes 15 generated through an impact ionization phenomenon are retained in the p layer 5. To this end, it is acceptable as long as the p layer 5 has a floating body structure isolated from the substrate 20. Accordingly, the foregoing dynamic flash memory operation can be performed even when the first gate conductor layer 1, the second gate conductor layer 2, and the p layer 5 are formed horizontally to the substrate 20 using a technology for producing GAA (Gate All Around; for example, see J. Y. Song, W. Y. Choi, J. H. Park, J. D. Lee, and B-G. Park: “Design Optimization of Gate-All-Around (GAA) MOSFETS,” IEEE Trans. Electron Devices, vol. 5, no. 3, pp. 186-191, (2006)) or a nanosheet (for example, see N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, (2017)). In this manner, it is acceptable as long as the dynamic flash memory element provided in the present embodiment satisfies the condition that its channel region has a floating body structure.

The present embodiment has the following features.

### (Feature 1)

According to the dynamic flash memory, which is one type of floating-body memory, of the present embodiment, it is possible to freely set the volume of a semiconductor for storing excess holes that determine writing to or erasing from the memory than conventional examples, and increase the volume, in comparison with the structure of a conventional dynamic flash memory in which the periphery of a semiconductor is covered with a gate electrode. Thus, the operation margin of the memory can be increased.

### (Feature 2)

According to the present embodiment, in comparison with the structure of a conventional three-dimensional dynamic flash memory in which the periphery of a semiconductor is covered with a gate electrode, it is possible to disperse a line of electric force from the gate electrode toward a channel portion of a MOS transistor, and thus increase the back-gate bias effect. This can increase the dependence of the threshold voltage on the number of excess holes stored in the floating body, and thus increase the difference between the threshold voltage for writing and that for erasing. Thus, the operation margin of the memory can be increased.

### (Feature 3)

According to the present embodiment, the number of excess holes that can be stored in the floating body can be increased. Thus, a memory, which has a long memory retention time and is resistant against read disturb failure, can be provided.

The present invention can be implemented in various embodiments and modifications without departing from the broad spirit and scope of the present invention. In addition, each of the foregoing embodiments only describes an example of the present invention and is not intended to limit the scope of the present invention. The foregoing examples and modified examples may be combined as appropriate. Further, even if some of the components of the foregoing embodiments are removed as needed, the resulting structure is within the technical idea of the present invention.

With the semiconductor elements according to the present invention, it is possible to provide a semiconductor memory device with higher density, higher operation speed, and higher operation margin than those of the conventional devices.

What is claimed is:

1. A memory device with semiconductor elements, comprising:
a first gate conductor layer and a second gate conductor layer extending in a horizontal direction or a vertical direction on a substrate, the first gate conductor layer and the second gate conductor layer being electrically isolated from each other by an insulating layer;
a first gate insulating layer partially covering the first gate conductor layer;
a second gate insulating layer partially covering the second gate conductor layer;
a semiconductor region in contact with each of the first gate insulating layer and the second gate insulating layer, the semiconductor region extending in parallel with an extension direction of the first and second gate conductor layers; and
a first impurity region and a second impurity region that are respectively continuous with opposite ends of the semiconductor region in the extension direction, and are electrically isolated from each other,
wherein
as seen in a horizontal cross-section, a length of the semiconductor region in contact with the first gate insulating layer is longer than a length of the first gate conductor layer in contact with the first gate insulating layer, or a length of the semiconductor region in contact with the second gate insulating layer is longer than a length of the second gate conductor layer in contact with the second gate insulating layer.

2. The memory device with semiconductor elements according to claim 1,
wherein as seen in a cross-section perpendicular to the extension direction of the first gate conductor layer and the second gate conductor layer, an outer peripheral length of the semiconductor region is greater than an outer peripheral length of the first gate conductor layer or the second gate conductor layer.

3. The memory device with semiconductor elements according to claim 1,
wherein the first impurity region is in contact with the semiconductor region at two or more positions.

4. The memory device with semiconductor elements according to claim 1,
wherein the second impurity region is in contact with the semiconductor region at two or more positions.

5. The memory device with semiconductor elements according to claim 1,
wherein the first impurity region is connected to a source line, the second impurity region is connected to a bit line, one of the first gate conductor layer and the second gate conductor layer is connected to a word line, and another of the first gate conductor layer and the second gate conductor layer is connected to a plate line, and
an operation of a dynamic flash memory is performed by applying a voltage to each of the source line, the bit line, the plate line, and the word line to execute a memory write operation, a memory read operation, and a memory erase operation.
